(19) United States
(12) Patent Application Publication
(10) Pub. No.: US 2012/0312585 A1
(43) Pub. Date: Dec. 13, 2012

(54) Soft Electrode Material and Manufacturing Method Thereof

(75) Inventors: Jong Tae Baek, Daejeon (KR); Moon Pyung Park, Ansan-si (KR); Hyung-Ho Park, Seoul (KR); Hyuncheol Kim, Seoul (KR); Jin-Seok Lee, Seoul (KR)

(73) Assignee: CIJ. CO., LTD., Daejeon (KR)

(21) Appl. No.: 13/580,796

(22) PCT Filed: Feb. 24, 2011
(86) PCT No.: PCT/KR2011/001305

§ 371 Date: Aug. 23, 2012

(30) Foreign Application Priority Data
Feb. 24, 2010 (KR) 10-2010-0016628
Feb. 24, 2011 (KR) 10-2011-0016279

(51) Int. Cl. H01B 1/04; B32B 25/20; H05K 1/00; B05D 5/12; B32B 9/04; B82Y 30/00

(52) U.S. Cl. 174/254; 427/77; 428/688; 428/446; 977/948; 977/734; 977/742

(57) ABSTRACT

There is provided a soft electrode material including an electrode layer containing a mixture of carbon black and at least one selected from carbon nanotube and graphene, so that the soft electrode material can facilitate various transformation thereof in response to physical transformation of an electrode, such as warpage, elongation, and the like; prevent the rapid reduction in electric conductivity of an electrode while maintaining flexibility and elasticity of the electrode at the time of the transformation; and provide excellent reliability, and thus, electrical-mechanical energy conversion efficiency of a soft electronic component such as an actuator including the soft electrode material, can be increased, and electric conductivity of the electrode layer can be improved as the electrical-mechanical conversion efficiency increases.

### TECHNICAL FIELD

The following disclosure relates to a soft electrode material, and more particularly to a soft electrode material useful for a display device and a soft electronic component such as an actuator or the like, which require flexibility and elasticity, and a soft electronic component such as a soft actuator or the like including the soft electrode material.

### BACKGROUND

Recently, an electrode formation technology using carbon or nano-metal has come into the spotlight. This electrode formation technology is utilized in a solar cell, a display device, an actuator, and the like, and is expected to be utilized in soft electronic products due to the request by the technology and market.

In particular, electrodes need to be formed on upper and lower surfaces of an elastic and flexible substrate in order to allow the electrode formation technology to be utilized in a soft electrode component considering elasticity, such as a haptic phone using a touch screen, and a technology development of a polymer based actuator having excellent electric characteristics and maintaining elasticity in order to allow the electrode formation technology to be applied to a touch screen through the manufacture of an actuator.

As known, the actuator means an apparatus of converting between electric energy and mechanical work at a macro-level or a micro-level, and electromechanical actuators based polymer has been studied for several decades.

For example, a conductive oxide such as indium tin oxide (ITO), a conductive particle such as a metal particle, or a conductive polymer, or the like may be used as an electrode material for the actuator. However, in the case where a film is formed of the conductive particles, electric characteristics of an electrode may be considerably deteriorated due to elongation of the actuator. In the case where a film is formed of the conductive polymers, an electrode is severely deteriorated and a sheet resistance of the electrode itself may be high. In the case where a film is formed of the conductive oxides, flexibility of the electrode may be degraded and a polymer based actuator itself may be thermally deformed due to a high-temperature process necessarily performed.

### SUMMARY

An embodiment of the present invention is directed to providing a soft electrode material, capable of facilitating various transformation thereof in response to physical transformation of an electrode, such as warpage, elongation, and the like; preventing a rapid reduction in electric conductivity of an electrode or a rapid increase in electric resistance of an electrode while maintaining flexibility and elasticity at the time of the transformation thereof; and having excellent reliability.

In one general aspect, a soft electrode material includes: an elastic and flexible substrate; and an electrode layer formed on at least one surface of the substrate, the electrode layer containing a mixture of carbon black and at least one selected from carbon nanotube and graphene.

The electrode layer may include at least one selected from carbon nanotube and graphene in an amount of 0.0001 to 10 parts by weight based on 100 parts by weight of the carbon black.

The electrode layer may include at least one selected from carbon nanotube and graphene in an amount of 0.001 to 1 parts by weight based on 100 parts by weight of the carbon black.

Here, a resistance changing rate according to the elongation of the soft electrode material may be 30% or less, the resistance changing rate according to the elongation being defined as follows:

Resistance changing rate according to the elongation(%)=sheet resistance value when elongation in a surface direction is performed by 10% of elongation rate−initial sheet resistance value/initial sheet resistance value×100.

The resistance changing rate according to the elongation of the soft electrode material may be 3 to 15%.

The carbon nanotube may have an aspect ratio distribution of a bi-modal, tri-modal, or more-modal distribution mode.

The carbon nanotube may have an aspect ratio distribution where two peaks selected from a first peak of 10 to 10², a second peak of 10³ to 10⁴, and a third peak of 10⁵ to 10⁶ are mixed.

The soft electrode material may have a sheet resistance of 0.01 to 800 kΩ/sq.

The elastic and flexible substrate may have dielectric property.

The elastic and flexible substrate may be silicon based rubber or elastic polymer.

In one general aspect, an actuator includes the soft electrode material which includes electrodes respectively formed on both facing surfaces of an elastic and flexible substrate.

In still another general aspect, a method for manufacturing a soft electrode material includes: preparing a first dispersion solution containing carbon black; preparing a second dispersion solution containing at least one selected from carbon nanotube and graphene; preparing an electrode forming dispersion solution by mixing the first dispersion solution and the second dispersion solution; coating the electrode forming dispersion solution on at least one surface of an elastic and flexible substrate; and drying the substrate coated with the electrode forming dispersion solution at room temperature.

The method may further include, after the preparing of the electrode forming dispersion solution, controlling viscosity of the electrode forming dispersion solution by volatilizing a solvent of the electrode forming dispersion solution.

The method may further include, after the drying, performing heat treatment at a temperature range of room temperature to 150° C. for 1 minute to 2 hours.

### BRIEF DESCRIPTION OF THE DRAWINGS

FIG. 1 shows one example of an electrode material according to the present invention;

FIG. 2 shows one example of an electrode layer in the electrode material according to the present invention;

FIG. 3 shows an aspect ratio distribution of carbon nanotubes (CNTs) contained in the electrode layer in the electrode material according to the present invention; and

FIG. 4 shows another example of the electrode layer in the electrode material according to the present invention.

### DETAILED DESCRIPTION OF EMBODIMENTS

Hereinafter, an electrode material and an actuator according to an embodiment of the present invention will be described in detail with reference to the accompanying drawings. The drawings exemplified below are provided by way of examples so that the spirit of the present invention can be sufficiently transferred to those skilled in the art to which the present invention pertains. Therefore, the prevent invention is not limited to the drawings set forth below, and may be embodied in different forms, and the drawings set forth below may be exaggerated in order to clarify the spirit of the present invention. Also, like reference numerals denote like elements throughout the specification.

Here, unless indicated otherwise, the terms used in the specification including technical and scientific terms have the same meaning as those that are usually understood by those who skilled in the art to which the present invention pertains, and detailed description of the known functions and constitutions that may obscure the gist of the present invention will be omitted.

A soft electrode material according to an embodiment of the present invention may include: an elastic and flexible substrate; and an electrode layer formed on at least one surface of the substrate, the electrode layer containing a mixture of carbon black and at least one selected from carbon nanotube and graphene.

Specifically, the electrode material according to the embodiment of the present invention is shrunken in a thickness direction thereof by a voltage applied to the electrode layer, and tensioned in a surface direction of the electrode layer, to thereby induce elastic transformation thereof. In addition, the number of contact points between carbon nanotube and carbon nanotube or between carbon nanotube and carbon black is increased by carbon nanotube included in the electrode layer at the time of elastic transformation of the electrode material, so that the rapid reduction in electric conductivity in a surface direction of the electrode material can be prevented. Meanwhile, the graphene means a carbon structure where a cylindrical carbon nanotube is spread in a surface type, and the graphene is a material having high electric characteristics due to π bonds in a surface thereof, like the carbon nanotube. The graphene can also prevent a rapid reduction in electric conductivity by increasing the number of contact points, like the carbon nanotube.

For this reason, in the electrode material according to the embodiment of the present invention, the electrode layer thereof may include at least one selected from carbon nanotube and graphene, in addition to carbon black.

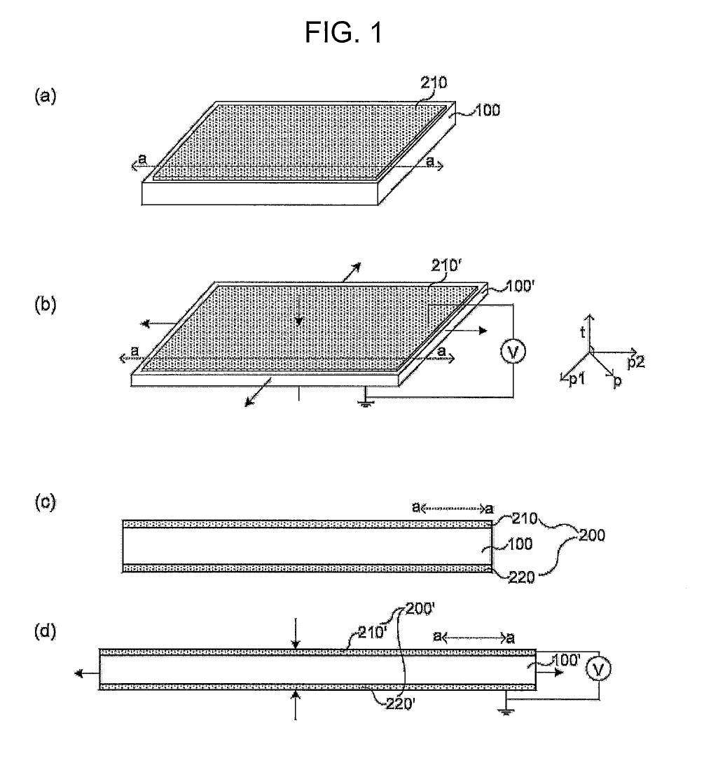

FIG. 1 shows one example of an electrode material according to the present invention. As shown in (a) of FIG. 1, the electrode material according to the present invention may include an elastic and flexible substrate 100 and electrode layers 200 respectively formed on two facing surfaces of the elastic and flexible substrate 100.

A case where the electrode layers are formed on both surfaces of the elastic and flexible substrate is exemplified herein, but the preset invention is not limited thereto. Also, the equivalent phenomena and effects to those described below are exhibited for a case where an electrode layer is formed on one surface of the substrate.

In the descriptions above and below, the “elastic and flexible substrate” means a substrate that is transformed when the substrate is elongated, bent, or warped, and then recovered to the original state thereof, which is particularly limited to the substrate.

However, in the embodiment of the present invention, the substrate may be an elastic polymer film or a silicon based rubber considering the application to soft electronic components, and, of course, a compositional ratio of the polymer is not limited. In addition, in the embodiment of the present invention, the “elastic and flexible substrate” may have or may not have dielectric property considering the application thereof.

As for the electrode material according to the embodiment of the present invention, an upper electrode layer 210 and a lower electrode layer 220 face each other with the elastic and flexible substrate 100. Therefore, when a voltage (V) is applied between the upper electrode layer 210 and the lower electrode layer 220 as shown in (b) of FIG. 1, electrostatic force is generated by charges induced in the two electrode layers 210 and 220.

This electrostatic force enables a mechanical pressure to be applied to the elastic and flexible substrate 100 in a thickness direction (t), so that, as shown by an arrow in (b) of FIG. 1, the elastic and flexible substrate 100 is shrunken in the thickness direction (t) and tensioned in a surface direction (p), that is, a direction that belongs to a surface of the electrode layer 200 formed on the elastic and flexible substrate 100.

Here, as shown in (b) of FIG. 1, the thickness direction (t) is a lamination direction at which the elastic and flexible substrate 100 and the electrode layers 200 are laminated, and corresponds to a thickness direction of the elastic and flexible substrate 100, the electrode layers 200, or the electrode material. Meanwhile, the surface direction is a direction perpendicular to the thickness direction. The surface direction is one of directions (p1, p2, p) that belong to the surface of the electrode layer 200 formed on the elastic and flexible substrate 100, and means any direction perpendicular to the thickness direction.

Meanwhile, (c) and (d) of FIG. 1 are cross-sectional views of (a) and (b) of FIG. 1, taken along the a-a direction, which show elastic transformation of the electrode material before and after a voltage is applied, respectively. As shown in (d) of FIG. 1, the elastic and flexible substrate 100 is transformed by electrostatic force generated by the voltage applied between the two electrode layers 200, and also, the upper electrode layer 210 and the lower electrode layer 220 formed on the elastic and flexible substrate 100 are shrunken in the thickness direction (t) and tensioned in the surface direction (p) together with the elastic and flexible substrate 100.

In the electrode material according to the embodiment of the present invention, the electrode layers 200 may contain a mixture of carbon black and at least one selected from carbon nanotube and graphene, as described above. Here, although the elastic and flexible substrate 100 and the electrode layers 200 are shrunken in the thickness direction (t) and tensioned in the surface direction (p) by the voltage applied between the electrode layers 200, the number of contact points between carbon nanotube and carbon nanotube or between carbon nanotube and carbon black is increased due to the presence of carbon nanotube, so that a rapid reduction in electric conductivity in the surface direction of the soft electrode material can be prevented. Graphene also can prevent a rapid reduction in electric conductivity by increasing the number of contact points, like the carbon nanotube. In other words, these electrode layers can facilitate various transformation thereof in response to physical transformation of an electrode, such as warpage, elongation, and the like; maintain elasticity and flexibility at the time of this transformation thereof; prevent a rapid reduction in electric conductivity of electrode due to the transformation; and have excellent reliability.

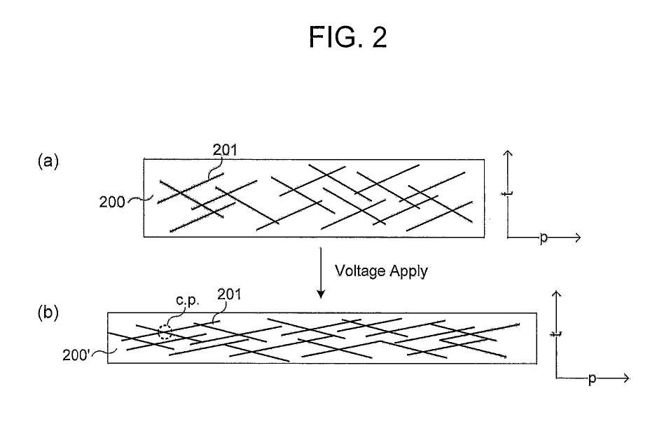

FIG. 2 specifically shows one example of the electrode layer 200 in the electrode material according to the embodiment of the present invention. As shown in (a) of FIG. 2, the electrode layer 200 may contain carbon black (not shown) and carbon nanotubes 201 having a large aspect ratio.

As the electrode layer 200 is transformed, carbon black density in the thickness direction (t) is increased and carbon black density in the surface direction (p) is decreased, and as the result, electric conductivity in the surface direction of the soft electrode material is reduced. When the electrode layer 200 contains carbon nanotubes 201 having a large aspect ratio, the carbon nanotubes 201 are distorted by compression stress in the thickness direction (t) and tensile stress in the surface direction (p), and thus, carbon nanotubes 201 having random directions are rearranged in parallel with the surface direction (p) of the elastic and flexible substrate 100.

As shown in (b) of FIG. 2, since the carbon nanotubes 201 are rearranged in parallel with the surface direction (p) by application of voltage to the electrode layer 200, the number of contact points (c.p. of (b) of FIG. 2) between carbon nanotube and carbon nanotube or between carbon nanotube and carbon black in the surface direction is increased, so that very reliable and stable electric conductivity (electric conductivity in the surface direction) can be obtained even though the electrode material is transformed.

FIG. 2 shows a case where the electrode layer 200 contains carbon nanotubes as well as carbon black. Of course, the graphene also exhibited the same effects as the carbon nanotube since the graphenes are rearranged in a similar type to the carbon nanotubes at the time application of voltage.

As described above, in the soft electrode material according to the present invention, the electrode layer 200 contains a mixture of carbon black and at least one selected from carbon nanotube and graphene, so that electric conductivity of the electrode layer 200 included in the electrode material can be improved by using physical transformation of the electrode material that causes the reduction in electric conductivity. For this reason, the rapid reduction in electric conductivity due to transformation is prevented, and thus, in the cases of soft electronic components such as an actuator or the like including the electrode material, electrical-mechanical energy conversion efficiency can be increased, and at the same time, electric conductivity of the electrode layer 200 can be improved as the electrical-mechanical conversion efficiency increases.

When the carbon nanotubes are included in the electrode layer 200, the aspect ratio of the carbon nanotube 201 may be preferably 10 to 10⁶ in order to increase the number of contact points due to rearrangement of the carbon nanotubes.

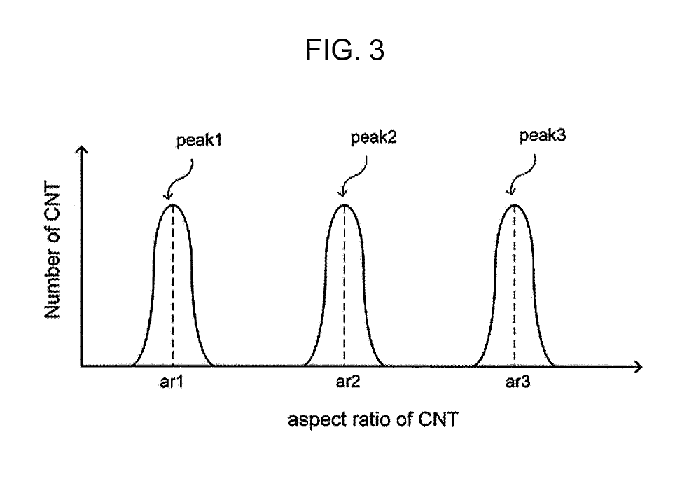

More preferably, in order to effectively increase the number of contact points in the surface direction due to rearrangement of the carbon nanotubes, the carbon nanotubes included in the electrode layer have a bi-modal, tri-modal, or more-modal distribution, based on the aspect ratio distribution of carbon nanotube. More specifically, in the aspect ratio distribution of carbon nanotubes, two or more peaks selected from a first peak of 10 to 10², a second peak of 10³ to 10⁴, and a third peak of 10⁵ to 10⁶ are mixed. For example, FIG. 3 shows one example where the carbon nanotubes 201 of the electrode layer 200 has a bi-modal or tri-modal distribution based on the aspect ratio distribution thereof.

As the aspect ratio distribution of carbon nanotubes 201 is a multimodal distribution having two or more peaks as shown in FIG. 3, more contact points are newly and effectively formed due to rearrangement of carbon nanotubes when a predetermined voltage (V) is applied between the electrode layers 200, and thus, the reduction in electric conductivity in the surface direction (p) is prevented regardless of the level of voltage (V) applied to the electrode material, and the electric conductivity in the surface direction (p) is stably maintained even at a transition state while the voltage (V) is applied to the electrode material. Therefore, when this electrode material is utilized as a soft electronic component such as an actuator or the like, the actuator is stably and reproducibly transformed even though a predetermine waveform of voltage is applied, and transformation of the actuator may be precisely controlled by the voltage that is varied.

Specifically, the aspect ratio distribution of carbon nanotubes 201 may preferably be a distribution having two or more peaks selected from a first peak (peak 1 of FIG. 3) having an average aspect ratio (ar1 of FIG. 3) of 10 to 10², a second peak (peak 2 of FIG. 3) having an average aspect ratio (ar2 of FIG. 3) of 10³ to 10⁴, and a third peak (peak 3 of FIG. 3) having an average aspect ratio (ar3 of FIG. 3) of 10⁵ to 10⁶.

In the aspect ratio distributions of the first to third peaks of carbon nanotubes 201, the reduction in electric conductivity in the surface direction (p) does not occur when the elastic and flexible substrate 100 and the electrode layer 200 of the soft electrode material are transformed.

As for control of the aspect ratio distribution of carbon nanotubes, a bimodal or more-modal distribution may be achieved by mixing two or more kinds of carbon nanotubes having different aspect ratio distributions.

The electrode layer 200 may contain carbon nanotube or graphene in preferably 0.0001 to 10 parts by weight, and more preferably 0.001 to 1 parts by weight, based on 100 parts by weight of carbon black. The above content range of carbon nanotube or graphene may be preferable in increasing the number of contact points between carbon nanotube (and/or graphene) and carbon nanotube (and/or graphene) and between carbon nanotube (and/or graphene) and carbon black due to rearrangement of carbon nanotubes or graphenes, to thereby prevent the reduction in electric conductivity in the surface direction (p) due to transformation of the soft electrode material.

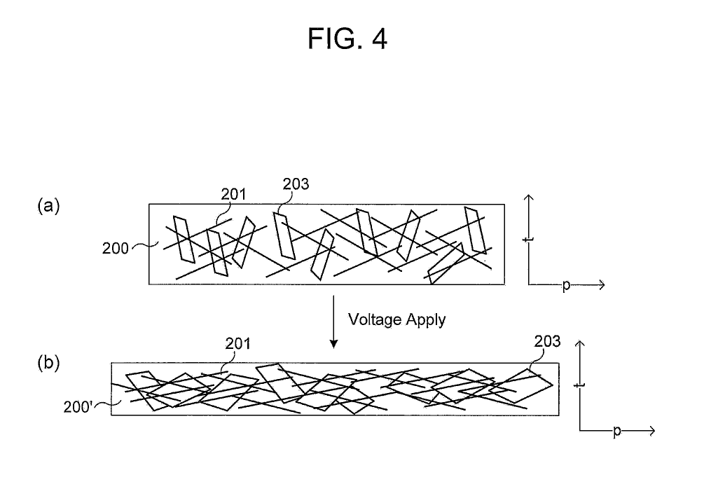

FIG. 4 shows one example of a case where the electrode layer 200 contains graphenes 203 as well as carbon black and carbon nanotubes 201. Together with the carbon nanotubes 201, the graphenes 203 having random directions are rearranged in parallel with the surface direction (p) of the elastic and flexible substrate 100 by compression stress in the thickness direction (t) and tensile stress in the surface direction (p), which are caused by the electrostatic force.

In the case where carbon nanotube and graphene are mixedly used together with carbon black, the number of contact points in the surface direction (p) between carbon nanotube and carbon nanotube, between carbon nanotube and carbon black, between carbon nanotube and graphene, between graphene and graphene, and between graphene and carbon black, is increased due to rearrangement of the carbon nanotubes 201 and graphene 203, thereby preventing the reduction in electric conductivity in the surface direction (p) due to transformation of the soft electrode material.

The physical transformation of the electrode material according to the embodiment of the present invention due to the application of electric energy may be mainly controlled by the level of voltage applied between the electrode layers 200, the dielectric constant of the elastic and flexible substrate 100, and the thickness of the elastic and flexible substrate 100, and specifically, may be controlled by Relation Expression 1 below.

Pel=∈·∈₀·(U²/z²) [Relation Expression 1]

(Pₑₗ is electrostatic pressure, ∈ is dielectric constant of the elastic and flexible substrate, ∈₀ is dielectric constant of vacuum, U is voltage applied between the electrode layers, and z is thickness of the elastic and flexible substrate)

As described above, since electric conductivity of the electrode layer 200 included in the actuator is improved by using physical transformation of the actuator, the thickness of the elastic and flexible substrate satisfies Relation Expression 2 below in order to maintain stable and reproducible electric conductivity of the electrode layer 200.

0.3×z≦z^{v}≦0.9×z [Relation Expression 2]

(z is thickness of the elastic and flexible substrate when voltage is not applied between the electrode layers, and z^{v} is thickness of the elastic and flexible substrate when voltage is applied between the electrode layers)

The elastic and flexible substrate 100 satisfies Relation Expression 1 at a predetermined level of voltage applied to the electrode material, and may be a dielectric elastic polymer or a silicon based rubber that is conventionally used in the electrode material. Examples of the elastic and flexible substrate 100 may include silicon rubbers, (meth)acrylate based polymers, and the like.

Examples of the carbon nanotube 201 may include a metallic single walled carbon nanotube, a double-walled carbon nanotube, and a multi-walled carbon nanotube; examples of the graphene 203 may include a single layered graphene and a multi-layered graphene; and examples of the carbon black may include agglomerate where fine graphite particles agglomerate together.

The electrode layer may be manufactured by preparing an electrode paste where a mixture of carbon black and at least one selected from carbon nanotube and graphene is dispersed in oil or gel and coating the electrode paste on at least one surface of the elastic and flexible substrate, followed by drying. The coating process may be performed by a spray method, a screen printing method, an ink jet method, a spin coating method, or the like.

More specifically, a method for manufacturing the electrode layer may include: preparing a first dispersion solution containing carbon black; preparing a second dispersion solution containing at least one selected from carbon nanotube and graphene; preparing an electrode forming dispersion solution by mixing the first dispersion solution and the second dispersion solution; coating the electrode forming dispersion solution on at least one surface of an elastic and flexible substrate; and drying the resultant substrate at room temperature. The electrode forming dispersion solution itself may be coated on the elastic and flexible substrate, but a process of controlling viscosity of the electrode forming dispersion solution by volatilizing a solvent of the electrode forming dispersion solution may be further performed considering process efficiency. In controlling viscosity of the electrode forming dispersion solution by volatilizing the solvent therein, when the viscosity thereof is controlled to be about 1,000 to 20,000 mPa·s, the electrode layer may be formed by coating the electrode forming dispersion solution, followed by merely drying at room temperature, while appropriate coating coverage is maintained.

As necessary, heat treatment is further performed at the time of forming the electrode layers, and the conditions therefor may not be particularly limited. When heat treatment is performed at a temperature range of room temperature to 150° C. for 1 minutes to 2 hours, the electrode layers can be formed while the elastic and flexible substrate is not transformed.

Due to the manufacturing process as above, the amount of conductive particles (carbon black, carbon nanotube, and graphene) contained in a dispersion medium of the electrode paste as well as the aspect ratio of carbon nanotube and the aspect ratio distribution of carbon nanotubes are controlled, and thus, the distance between two conductive particles selected from carbon black, carbon nanotube, and graphene of the electrode layer, which is formed by coating the electrode forming dispersion solution, the surface density thereof, and distribution of the distance are controlled, so that the rate of increase in the number of contact points between the conductive particles due to transformation of the elastic and flexible substrate can be controlled.

In this soft electrode material, the electrode layer may be useful for the electrode material as long as the electrode layer has a sheet resistance of 0.01 to 800 kΩ/sq.

This electrode material may be utilized as a soft electronic component such as an actuator or the like. Particularly, considering application to the actuator, the electrode material may have electrode layers respectively formed on both facing surfaces of the substrate.

Besides, the electrode material according to the embodiment of the present invention may be, of course, utilized for a flexible PCB, a flexible display, a roll display, a wearable computer, or other flexible electronic components.

A carbon electrode layer was manufactured by using multi-walled carbon nanotubes (MWCNTs) through the process as above, and then the following experiment was conducted in order to observe the effects of the multi-walled carbon nanotubes (MWCNTs) added on the resistance change according to the elongation of the carbon electrode layer.

As a specific example for manufacturing the carbon electrode layer, a carbon black dispersion solution was prepared by dispersion of carbon black paste (4 g), and separately, a carbon nanotube dispersion solution was prepared by performing ultrasonic treatment on a dispersion solution containing the multi-walled carbon nanotubes (based on the aspect ratio distribution of carbon nanotubes, a peak of 10 to 10² and a peak of 10³ to 10⁴ are mixed). The distribution type of carbon nanotubes may be observed by a scanning electron microscope.

A mixture solution obtained by stirring the thus obtained carbon black dispersion solution and the thus obtained carbon nanotube dispersion solution was screen-printed on an elastic and flexible substrate (latex film) to thereby form an electrode layer (thickness: 7.5 μm), which was then dried at room temperature. Then, heat treatment was performed on the resultant structure at a temperature of room temperature to 150° C. for 1 minutes to 2 hours, to thereby obtain a latex film on which a carbon electrode layer is formed.

First, in forming the electrode layer through the room-temperature drying and heat treatment as described above, the decrease in electric resistance and agglomeration at the time of coating thereof according to the concentration of multi-walled carbon nanotubes were observed in order to confirm the optimal content range of multi-walled carbon nanotubes included in the electrode layer, and the results were summarized in Table 1 below.

TABLE 1

| Added amount of | | Sheet resistance | |
|---|---|---|---|
| multi-walled | | value after room- | Sheet resistance |
| carbon nanotubes | | temperature drying | value after heat |
| (g) | | (kΩ/sq) | treatment (kΩ/sq) |
| 0 | g | 131.1 | 93 |
| 0.006 | | 82.43 | 43 |
| 0.012 | | 74.07 | 39.26 |
| 0.024 | | 19.5 | 9.75 |

It can be confirmed from the results of Table 1 above, that the addition of multi-walled carbon nanotubes lowered a sheet resistance value of the electrode layer, considering a case where the electrode layer contains only carbon black, that is, the added amount of multi-walled carbon nanotubes is 0 g. However, as the added amount thereof is increased, the carbon nanotubes are difficult to disperse, which may cause agglomeration of the carbon nanotubes.

It can be confirmed that the content of carbon nanotubes is 0.0001 to 10 parts by weight and more preferably 0.001 to 1 parts by weight, based on 100 parts by weight of carbon black.

Next, based on the above experiment, there was manufactured a specimen including 0.001 g or more of multi-walled carbon nanotubes, that exhibits a low sheet resistance and does not occur agglomeration. In order to confirm effects of carbon nanotubes added on the resistance change according to the elongation of the carbon electrode, resistance values according to the elongation for the specimen were measured, and the results were summarized in Table 2 below.

Here, elongation was performed by using an elongation tester, and resistance values were measured by using a multi-tester.

The resistance value described in Table 2 means a sheet resistance.

In Table 2, a control indicates cases where the electrode layer includes only carbon black.

TABLE 2

| Elongation | Control | Present |
|---|---|---|
| ratio (%) | (kΩ) | Invention (kΩ) |
| 0 | 2.32 | 4.13 |
| 10 | 3.12 | 4.47 |
| 25 | 4.533 | 4.96 |
| 50 | 5.78 | 5.6 |
| 75 | 7.14 | 6.36 |
| 100 | 8.87 | 7.13 |

It can be seen from the results of Table 2, that the resistance value of the specimen before elongation was higher in the present invention than in the control, but this may result rather from effects by the compositional ratio of the electrode layer than from a difference in thickness of the electrode layer between the control and the present invention. Meanwhile, it can be confirmed that, in the resistance values measured according to the increase in elongation ratio, the resistance value in the control was significantly increased, but the change in resistance value in the present invention was significantly smaller than that in the control. This may result from the increase in the number of contact points which is caused by including carbon nanotubes in the electrode layer.

It can be confirmed from these results, that in the electrode material according to the embodiment of the present invention, the resistance change rate according to the elongation thereof, which is defined as follows, exhibited a value of 30% or less.

Resistance change rate(%) according to the elongation=sheet resistance value when elongation in a surface direction is performed by 10% of elongation rate−initial sheet resistance value/initial sheet resistance value×100

Ultimately, the content, the aspect ratio distribution, and the like, of carbon nanotubes or graphenes included in the electrode layer may be controlled to satisfy this resistance change rate according to the elongation.

Meanwhile, although shown in the present experiment, the resistance change rate of the carbon electrode is increased in the case where the added amount of carbon nanotubes is small, and the resistance change rate of the carbon electrode is decreased in the case where the added amount of carbon nanotubes is large. However, the above-described two cases have the same effect in that the addition of carbon nanotubes lowers the resistance change rate according to the elongation of the soft electrode material.

Meanwhile, one example of the carbon electrode including carbon nanotubes in the electrode layer is shown above, but the graphene may also exhibit the same effects like the carbon nanotube.

The graphene has a carbon structure where a cylindrical carbon nanotube is spread in a surface type, and the graphene is a material having high electric characteristics due to π bonds in a surface thereof, like carbon nanotube. These graphenes also exhibit the same effect of increasing the number of contact points due to the addition of carbon nanotubes in the carbon electrode, and eventually, may be anticipated to lower the resistance change rate according to the elongation.

From the experiments above, it can be confirmed that the soft electrode material of the present invention can facilitate various transformation in response to physical transformation of electrode, such as warpage, elongation, and the like; prevent rapid reduction in electric conductivity of electrode while maintaining flexibility or elasticity at the time of the transformation thereof; and have excellent reliability. In addition, it can be confirmed that the soft electrode material of the present invention can prevent the rapid reduction in electric conductivity regardless of the transformation degree of electrode, and maintain stable electric conductivity even while the electrode is transformed.

As set forth above, the soft electrode material according to the present invention can facilitate various transformation thereof in response to physical transformation of an electrode, such as warpage, elongation, and the like; compensate for the reduction in electric conductivity of an electrode due to the above transformation and prevent the rapid reduction in electric conductivity of an electrode due to the physical transformation of the electrode, to thereby provide stable electric conductivity; provide reliable and stable electric conductivity while maintaining flexibility and elasticity of the electrode; prevent the rapid reduction in electric conductivity regardless of the transformation degree of an electrode; and maintain stable electric conductivity even while the electrode is transformed. Therefore, these electrodes may be useful in the soft electronic components such as actuator and the like.

As described above, although the present invention is described by specific matters such as concrete components and the like, exemplary embodiments, and drawings, they are provided only for assisting in the entire understanding of the present invention. Therefore, the present invention is not limited to the exemplary embodiments. Various modifications and changes may be made by those skilled in the art to which the present invention pertains from this description.

Therefore, the spirit of the present invention should not be limited to the above-described exemplary embodiments, and the following claims as well as all modified equally or equivalently to the claims are intended to fall within the scopes and spirit of the invention.

1. A soft electrode material for an electrode layer:
an elastic and flexible substrate; and
an electrode layer formed on at least one surface of the substrate, the electrode layer containing a mixture of carbon black and at least one selected from carbon nanotube and graphene.

2. The soft electrode material of claim 1, wherein the electrode layer includes at least one selected from carbon nanotube and graphene in an amount of 0.0001 to 10 parts by weight based on 100 parts by weight of the carbon black.

3. The soft electrode material of claim 1, wherein the electrode layer includes at least one selected from carbon nanotube and graphene in an amount of 0.001 to 1 parts by weight based on 100 parts by weight of the carbon black.

4. The soft electrode material of claim 1, wherein a resistance changing rate according to the elongation thereof is 30% or less, the resistance changing rate according to the elongation being defined as follows:
resistance changing rate according to the elongation(%)=sheet resistance value when elongation in a surface direction is performed by 10% of elongation rate−initial sheet resistance value/initial sheet resistance value×100.

5. The soft electrode material of claim 1, wherein the resistance changing rate according to the elongation thereof is 3 to 15%.

6. The soft electrode material of claim 1, wherein the carbon nanotube has an aspect ratio distribution of a bi-modal, tri-modal, or more-modal distribution mode.

7. The soft electrode material of claim 6, wherein the carbon nanotube has an aspect ratio distribution where two peaks selected from a first peak of 10 to 10², a second peak of 10³ to 10⁴, and a third peak of 10⁵ to 10⁶ are mixed.

8. The soft electrode material of claim 1, wherein the electrode layer has a sheet resistance of 0.01 to 800 kΩ/sq.

9. The soft electrode material of claim 1, wherein the elastic and flexible substrate has dielectric property.

10. The soft electrode material of claim 1, wherein the elastic and flexible substrate is silicon based rubber or elastic polymer.

11. An actuator comprising the soft electrode material of claim 1 which includes electrodes respectively formed on both facing surfaces of an elastic and flexible substrate.

12. A method for manufacturing a soft electrode material, the method comprising:
preparing a first dispersion solution containing carbon black;
preparing a second dispersion solution containing at least one selected from carbon nanotube and graphene;
preparing an electrode forming dispersion solution by mixing the first dispersion solution and the second dispersion solution;
coating the electrode forming dispersion solution on at least one surface of an elastic and flexible substrate; and
drying the substrate coated with the electrode forming dispersion solution at room temperature.

13. The method of claim 12, further comprising, after the preparing of the electrode forming dispersion solution, controlling viscosity of the electrode forming dispersion solution by volatilizing a solvent of the electrode forming dispersion solution.

14. The method of claim 12, further comprising, after the drying, performing heat treatment at a temperature range of room temperature to 150° C. for 1 minute to 2 hours.
